(19) United States
(12) Patent Application Publication
(10) Pub. No.: US 2025/0357282 A1
(43) Pub. Date: Nov. 20, 2025

(54) DEVICE PACKAGE HAVING A CAVITY WITH SLOPED SIDEWALLS

(71) Applicant: SEMICONDUCTOR COMPONENTS INDUSTRIES, LLC, Scottsdale, AZ (US)

(72) Inventors: Ankit Bhushan SHARMA, Erding (DE); Olaf ZSCHIESCHANG, Sinsheim (DE)

(73) Assignee: SEMICONDUCTOR COMPONENTS INDUSTRIES, LLC, Scottsdale, AZ (US)

(21) Appl. No.: 18/959,003

(22) Filed: Nov. 25, 2024

Related U.S. Application Data
(60) Provisional application No. 63/649,068, filed on May 17, 2024.

(51) Int. Cl. H01L 23/495; H01L 21/48; H01L 21/56; H01L 23/31; H01L 25/07

(52) U.S. Cl. CPC H01L 23/49548; H01L 21/4842; H01L 21/565; H01L 23/3135; H01L 23/49562; H01L 25/072

(57) ABSTRACT

A semiconductor device package may include a conductive member having a cavity formed therein, the cavity having at least one sidewall with an angled portion that is angled away from a middle portion of the cavity. The semiconductor device package may include a semiconductor device positioned within the cavity and surrounded by an encapsulant. The at least one sidewall may have a chamfered or beveled edge.

### CROSS-REFERENCE TO RELATED APPLICATION

This application claims the benefit of and priority to U.S. Provisional Application No. 63/649,068, filed May 17, 2024, which is incorporated by reference herein in its entirety.

### TECHNICAL FIELD

This description relates to semiconductor device packaging.

### BACKGROUND

Semiconductor device packaging generally involves encasing one or more semiconductor devices in a protective housing that provides for electrical connections, heat dissipation, mechanical support, and/or electrical isolation. Many different types of semiconductor device packaging exist, providing varying degrees of packaging parameters. Such packaging parameters may include, but are not limited to, performance (e.g., speed or power handling performance) parameters, cost parameters, and/or size parameters.

### SUMMARY

According to one general aspect, a semiconductor device package includes a conductive member having a cavity formed therein, the cavity having at least one sidewall with an angled portion that is angled away from a middle portion of the cavity, and a semiconductor device positioned within the cavity.

According to another general aspect, a package for an embedded semiconductor device includes a substrate having a cavity formed therein, the cavity having at least one angled sidewall. The package for an embedded semiconductor device further includes at least one semiconductor device disposed within the cavity, and an encapsulant surrounding the at least one semiconductor device within the cavity.

According to another general aspect, a method of forming a semiconductor device package includes forming a cavity within a substrate, the cavity having at least one angled sidewall. The method further includes disposing at least one semiconductor device within the cavity and encapsulating the at least one semiconductor device within the cavity with an encapsulant.

The details of one or more implementations are set forth in the accompanying drawings and the description below. Other features will be apparent from the description and drawings, and from the claims.

### BRIEF DESCRIPTION OF THE DRAWINGS

FIG. 1 illustrates a semiconductor device package that includes a substrate having a cavity with angled sidewalls.

FIG. 2A is a cross-sectional side view corresponding to the example of FIG. 1, illustrating a chamfered edge.

FIG. 2B is an alternate example embodiment, illustrating a cross-sectional side view similar to the example of FIG. 1, with a beveled edge.

FIG. 3 is an alternate cross-sectional side view of the example of FIG. 2A.

FIG. 4 is a cross-sectional side view of the example of FIG. 1 with multiple semiconductor devices included.

FIG. 5 is a cross-sectional side view of the example of FIG. 4, illustrating an example encapsulation of the example of FIG. 4.

FIG. 6A illustrates a first example encapsulation of the embodiment of FIG. 2A.

FIG. 6B illustrates a second example encapsulation of the embodiment of FIG. 2A.

FIG. 7 illustrates a first example operation for manufacturing the embodiments of FIGS. 2-6B.

FIG. 8 illustrates a second example operation for manufacturing the embodiments of FIGS. 2-6B.

FIG. 9 illustrates a third example operation for manufacturing the embodiments of FIGS. 2-6B.

FIG. 10 illustrates a fourth example operation for manufacturing the embodiments of FIGS. 2-6B.

FIG. 11 illustrates a fifth example operation for manufacturing the embodiments of FIGS. 2-6B.

FIG. 12 illustrates a sixth example operation for manufacturing the embodiments of FIGS. 2-6B.

FIG. 13 illustrates a seventh example operation for manufacturing the embodiments of FIGS. 2-6B.

FIG. 14 is a flowchart illustrating example operations for manufacturing the semiconductor device packages of FIGS. 1-6B, corresponding to the example operations of FIGS. 7-13.

### DETAILED DESCRIPTION

Described techniques and embodiments provide improved semiconductor device packaging, including facilitating assembly, increasing safety margins, improving electrical isolation, and enhancing encapsulation. For example, one or more semiconductor devices may be provided within a cavity formed within a substrate, where one or more sidewalls of the cavity are sloped or angled away from the semiconductor device(s).

Forming the cavity sidewalls in this manner provides an opening near the top of the cavity that is wider than an opening at the bottom or floor of the cavity. Insertion and placement of the semiconductor device(s) within the cavity may thus be facilitated. For example, the semiconductor device(s) may be inserted and centered within the cavity, without making contact with the sidewalls during insertion. Consequently, assembly of the resulting semiconductor device package may be improved, as compared to existing assembly techniques.

Once the semiconductor device(s) is placed within the cavity, the semiconductor device(s) may be encapsulated with a suitable encapsulant (e.g., epoxy, polymer, resin, or mold material). In such cases, the sloped cavity sidewalls provide a wider opening to receive the encapsulant, as compared to cavities with straight sidewalls. As a result, a flow of the encapsulant into the cavity and around the semiconductor device(s) may be improved during lamination operations, thereby ensuring more complete and more consistent encapsulation.

Further, following assembly of the semiconductor device package, the sloped sidewalls provide an increased distance between a top of the semiconductor device(s) and the tops of the cavity sidewalls. This increased distance provides high safety margins and isolation capabilities between semiconductor device(s) and the substrate.

In various embodiments, the sloped sidewalls may be chamfered or beveled. Sloped sidewalls may be sloped at 45 degrees, or at any suitable or desired angle. The cavity, including the sloped sidewalls, may be formed using mechanical techniques (e.g., mechanical stamping or mechanical milling) and/or chemical techniques (e.g., etching). For example, the cavity may be formed using a mechanical stamp, and then sharp edges/corners of the cavity sidewalls may be reduced using chemical etching techniques. In other example implementations, sharp edges/corners may be removed using barrel tumbling techniques.

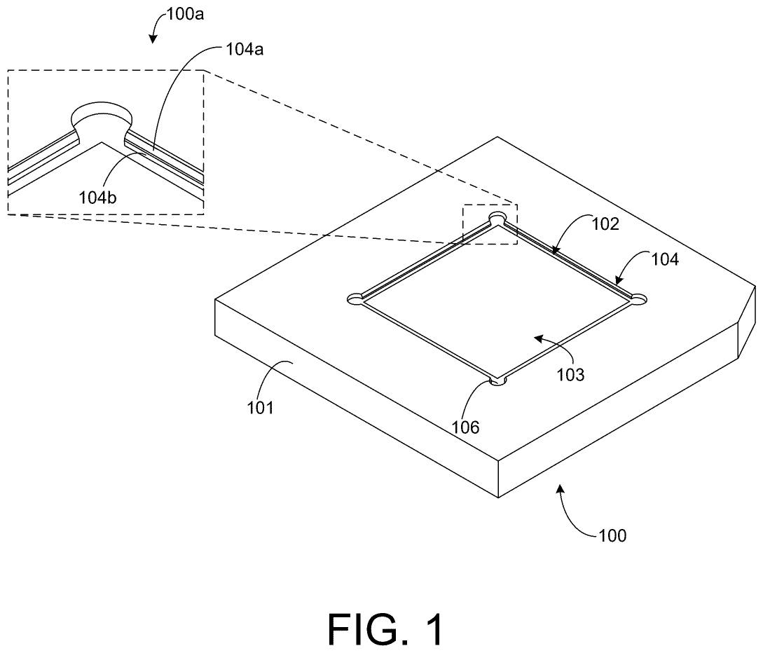

FIG. 1 illustrates a semiconductor device package 100 that includes a substrate 101 having a cavity 102, which may also be referred to as a recess, hole, or opening. As shown, a semiconductor device 103 may be positioned within the cavity 102, representing, e.g., any suitable semiconductor die or chip. The semiconductor device package 100 may include various other features not shown in FIG. 1 for the sake of clarity and brevity, such as an encapsulant that encapsulates the semiconductor device 103 and various types of electrical connections. Some examples of such features are provided below, but are not limiting with respect to possible features of the semiconductor device package 100.

In the example of FIG. 1, the cavity 104 is illustrated with angled sidewalls 104. As referenced above, and described in more detail, below, one or more of the angled sidewalls 104 may be angled away from a middle portion, e.g., a center, of the cavity 102. For example, as shown, all of the sidewalls (e.g., all four sidewalls) may be angled. In other example implementations, fewer than all of the sidewalls may be angled, e.g., two opposed sidewalls may be angled, and/or different sidewalls (or pairs of sidewalls) may be angled at different angles.

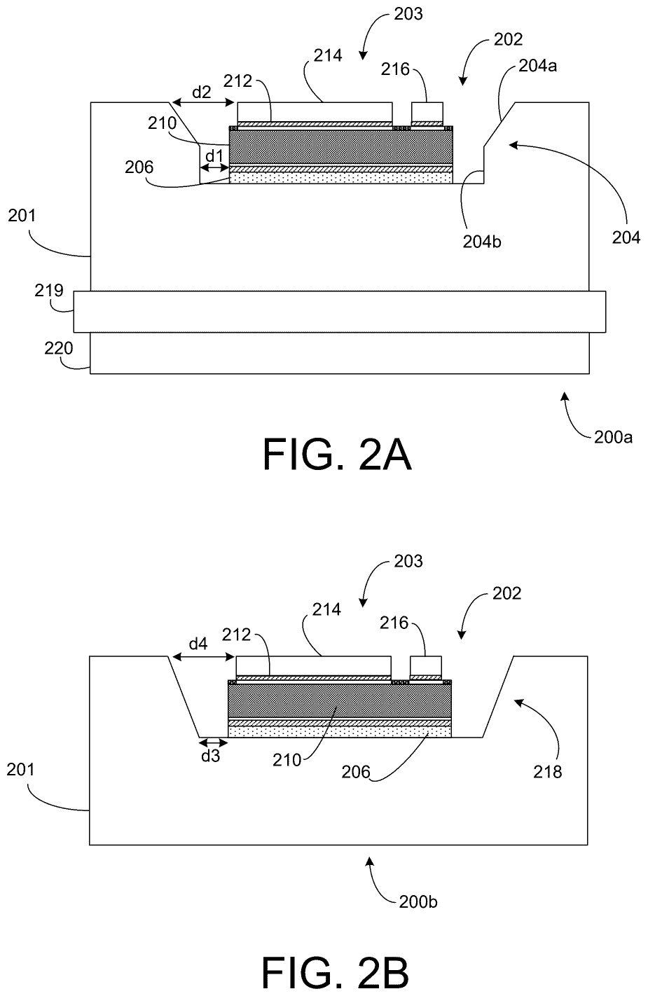

The angled sidewalls 104 may be partially or entirely sloped, using any desirable or available angle(s). For example, as illustrated in the exploded view 100a, the angled sidewalls 104 may be constructed with a chamfered edge, in which an upper portion(s) 104a of the angled sidewalls 104 is angled with respect to the semiconductor device 103 and to the floor of the cavity 102, while a lower portion(s) 104b of the angled sidewalls 104 is less angled, e.g., is perpendicular to the floor of the cavity 102. As discussed in more detail, below, FIG. 2A provides a more detailed example of an embodiment with a chamfered edge, while FIG. 2B provides an example of the angled sidewalls 104 with a beveled edge, in which an entirety of each of the angled sidewalls 104 is sloped away from the semiconductor device 103 at a constant angle with respect to the cavity floor.

As referenced above, the angled sidewalls 104 facilitate placement and centering of the semiconductor device 103 within the cavity 102. For example, the angled sidewalls 104 provide a greater area and perimeter of the cavity 102 at a top surface of the cavity 102, as compared to a floor of the cavity 102. Therefore, placement tools placing the semiconductor device 103 within the cavity 102 have a greater margin of error as the semiconductor device 103 is positioned with respect to a center of the cavity 102 and placed within the cavity 102.

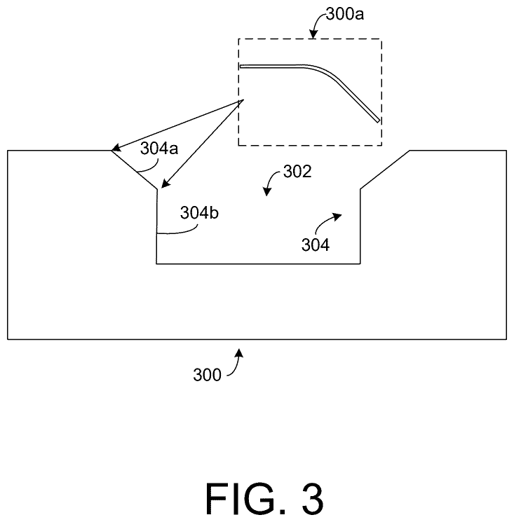

Once placed, the increased area at a top of the cavity 102 also facilitates encapsulation of the semiconductor device 103, as any encapsulant(s) has a greater area through which to enter the cavity 102 and surround (e.g., flow over and around) the semiconductor device 103. Following encapsulation, the increased distance between the semiconductor device 103 and the angled sidewalls 104 at a top of the cavity 102 reduces the chances of short-circuit events and generally increases a reliability of the semiconductor device package 100. Additional features and advantages of the angled sidewalls 104 are provided below, e.g., with respect to FIGS. 2A, 2B, and 3.

FIG. 1. also illustrates rounded corners 106 of the cavity 102. The rounded corners 106 reduce the chance that a corner of the semiconductor device 103 will contact the substrate 101 during insertion of the semiconductor device 103 into the cavity 102, which may result in breakage or other damage to the semiconductor device 103.

FIG. 2A is a cross-sectional side view corresponding to the example of FIG. 1, illustrating a chamfered edge. In the example of FIG. 2A, a semiconductor device package 200a includes a substrate 201 having a cavity 202 with angled sidewalls 204. As shown, a semiconductor device 203 may be positioned within the cavity 202.

As referenced above with respect to FIG. 1, the angled sidewalls 204 may be constructed with a chamfered edge, in which a lower portion 204b of each sidewall 204 is perpendicular to a floor of the cavity 202 and an upper portion 204a of each sidewall 204 is angled away from a centerline of the cavity 202 and from the semiconductor device 203.

Put another way, the lower portion 204b provides a vertical wall portion of the cavity 102 and the upper portion 204a provides an angled wall portion of the cavity 102, resulting in the sidewalls 104 having chamfered edges. Each such chamfered edge thus provides a non-uniform, e.g., graduated, distance d2 between the semiconductor device 203 and the substrate 201 at or near a top of the semiconductor device 203 that is greater than a distance dl between the semiconductor device 203 and the substrate 201 at or near a bottom of the semiconductor device 203.

In the example of FIG. 2A, the substrate 201 may represent any conductive member providing a suitable mounting surface or mounting member in which the cavity 202 may be formed and in which the semiconductor device 203 may be positioned. For example, the substrate 201 may represent a conductive member such as a leadframe, e.g., a metal leadframe (e.g., a copper leadframe).

In FIG. 2A, an additional conductive portion 220 is separated from the substrate 201 by an isolation layer 219. For example, the isolation layer 219 may be a ceramic isolation layer, or any suitable isolating, non-conductive material. Although not illustrated explicitly in subsequent examples, it will be appreciated that such an isolation layer and secondary conductive portion may be included in any of the illustrated and described embodiments.

More generally, the substrate 201 may be implemented as a single material or multiple materials. For example, the substrate 201 may include multiple layers in a direct bonded metal (DBM) or direct bonded copper (DBC) structure, in which a dielectric material is sandwiched between two metal (e.g., copper or aluminum) material(s). The substrate 201 may be part of a larger printed circuit board (PCB) and panel assembly.

In the example of FIG. 2A, a die attach material 206 attaches the semiconductor device 203 to the substrate 201 within the cavity 202. For example, the die attach material 206 may include Ag sinter or solder.

A first or bottom metallization layer 208 is formed on a semiconductor chip or die 210 of the semiconductor device 203, between the semiconductor die 210 and the substrate 201, and using any suitable metal (e.g., alloys of Titanium, nickel, silver). A second or top metallization layer 212 is formed on the semiconductor die 210 on an opposed side of the semiconductor die 210, and using any suitable metal (e.g., Al). As shown, the first/bottom metallization layer 208 is formed in full electrical contact with the substrate 201, while the second/top metallization layer 212 is patterned to connect with a first contact 214 and a second contact 216. The first contact 214 and second contact 216 may be formed, e.g., using plated Cu.

More generally, the metallization process(es) can include one or more metal and/or one or more insulating layers that can function as build-up layers that can result in one or more of the source contact 214 and the drain contact 216 being multi-layer structures. In some implementations, the metallization layers can be added after embedding the semiconductor device 203 in the substrate 201.

In the example of FIG. 2A, the semiconductor device 203 represents a transistor in which the substrate 201 provides a drain contact, the first contact 214 provides a source contact, and the second contact 216 provides a gate contact. The transistor may be any suitable transistor made from any suitable material, such as a Silicon (Si), Si Carbide (SiC), or Gallium Nitride (GaN) transistor. Of course, these are just examples, and various types of semiconductor devices, e.g., diodes, may be included, or combinations of devices (e.g., transistors, diodes) may be included within the cavity 202.

For example, the semiconductor device 203 may represent various types of power transistors, such as insulated-gate bipolar transistors (IGBTs), power metal-oxide-semiconductor field effect transistors (MOSFETs), and so forth. Electrical interconnections within a high-power semiconductor device package can include, for example, bond wires, conductive spacers, metal and insulating built up layers, and conductive clips.

The substrate 201 may be implemented as, or in conjunction with, a lead frame that is used to provide external electrical connections to the high-power semiconductor device package. For example, some of the high-power assemblies described herein can operate at voltages in a range of about 200 V to about 800 V. Such high-power chip assemblies, encapsulated as embedded semiconductor device modules, can be used in various applications, including electric vehicles (EVs), hybrid electric vehicles (HEVs), and industrial applications.

In the example of FIG. 2A, a top surface of the semiconductor device 203 (e.g., top surfaces of the first contact 214 and the second contact 216) are coplanar with a top surface of the substrate 201. In other words, a height of the semiconductor device 203 is approximately the same as a depth of the cavity 202. In other examples, however, the height of the semiconductor device 203 may not be the same as a depth of the cavity 202, e.g., may be greater or lesser than the depth of the cavity 202.

In the examples of FIGS. 1 and 2A, the distances d1, d2 may be uniform around a perimeter of the semiconductor device 103/203, but such uniformity is not required. For example, the cavity 202 may not be a square or other equal-sided shape, resulting in different distances d1, d2, on different sides of the semiconductor device 103/203. In other examples, there may be two or more devices within the cavity 102/202, so that two sides of two devices are adjacent to one another, rather than to a sidewall of a corresponding cavity.

FIG. 2B is an alternate example embodiment, illustrating a cross-sectional side view similar to the example of FIG. 1, with a beveled edge. That is, as shown in the semiconductor device package 200b of FIG. 2B, an angled sidewall 218 may be entirely straight between a floor of the cavity 202 and a top of the substrate 201. Accordingly, distance d3 between the semiconductor device 203 and the sidewall 218 at a floor of the cavity 202 and d4 between the semiconductor device 203 and the sidewall 218 near a top of the substrate 201 are defined, where d4 is greater than d3. In other words, the distances d3, d4 (e.g., a difference between the distances d4, d3) define the inclination angle of the sidewall 218.

It will be appreciated that the FIGS. 2A and 2B are non-limiting examples, and various implementations may include any angled sidewalls for which a distance between the semiconductor device 203 and the sidewall 218 at a floor of the cavity 202 is less than a distance between the semiconductor device 203 and the sidewall 218 near a top of the substrate 201. For example, an angle of the beveled edge of FIG. 2B or the chamfered edge of FIG. 2A may be increased or decreased to provide correspondingly more or less spacing near a top of the cavity 202 for placing and encapsulating the semiconductor device 203.

In general, the embedded device structures of FIGS. 1, 2A, and 2B, as well as the various embedded device structures described and illustrated below, can offer improved performance over surface-mounted dies, e.g., due to shorter connections, which are therefore faster. Embedded devices can also result in a semiconductor package that is more compact, and by extension, can result in, for example, a miniaturized printed circuit board (PCB).

In some implementations, one or more of the described semiconductor devices can be packaged using embedded die packaging technology in which one or more of the semiconductor devices can be embedded in a PCB, as opposed to being mounted on a surface of the PCB. When a system-on-chip (SOC), or multiple chips, are embedded in a PCB, a resulting system can be referred to as a system-in-board (SiB). In some implementations, to further enhance performance, one or more semiconductor devices can be embedded in the substrate 201, and can then also be packaged using embedded die packaging.

FIG. 3 is an alternate cross-sectional side view of the example of FIG. 2A. FIG. 3 illustrates a semiconductor device package 300 with a cavity 302 and chamfered sidewalls 304, and omits further illustration of a semiconductor device within the cavity 302.

FIG. 3 illustrates that a vertical sidewall portion 304b may be varied in height relative to an angled sidewall portion 304a of the chamfered edge 304, and relative to the example of FIG. 2A. That is, in various embodiments, the vertical sidewall portion 304b may be a greater or lesser portion of a total height of the chamfered edge 304. Moreover, the angled sidewall portion 304a may be positioned at any suitable angle, e.g., 45 degrees.

Further, as shown in exploded view 300a, sharp corners of the chamfered edge 304 may be rounded off, e.g., to reduce electrical field density variations. For example, as described in more detail, below, formation of the cavity 302 by mechanical means (e.g., by mechanical stamping) may result in formation of sharp corners of the chamfered edge 304, and subsequent processing (e.g., chemical etching, micro-etching, and/or barrel tumbling processes) may be used to provide rounding off of the sharp corners.

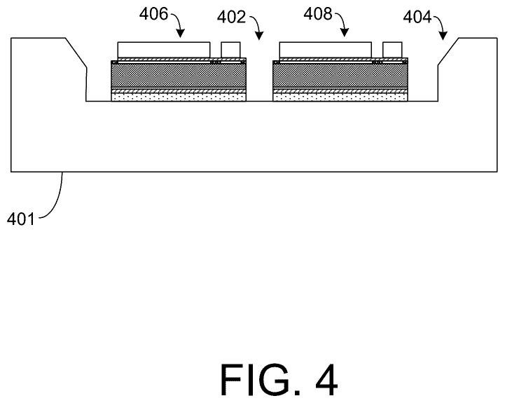

FIG. 4 is a cross-sectional side view of the example of FIG. 1 with multiple semiconductor devices included. In FIG. 4, a substrate 401 has a cavity 402 with angled sidewalls 404 formed therein. In the example of FIG. 4, a first semiconductor device 406 and a second semiconductor device 408 are disposed within the cavity 402. The semiconductor devices 406, 408 may be attached to the substrate 401 using any suitable technique, including, e.g., Ag sintering, solder bonding, or diffusion bonding.

The embodiment of FIG. 4 facilitates, e.g., parallel device connection to accommodate higher currents and higher power density (i.e., higher current in a smaller footprint than conventional devices). Although FIG. 4 illustrates the two semiconductor devices 406, 408, three or more devices may be included within the cavity 402.

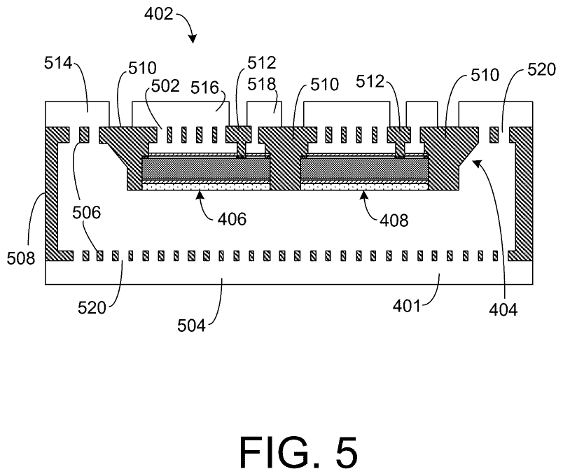

FIG. 5 is a cross-sectional side view of the example of FIG. 4, illustrating an example encapsulation of the example of FIG. 4. That is, FIG. 5 illustrates the example of FIG. 4, following an embedding process.

In the example of FIG. 5, encapsulant 506, 508, 510, 512 embeds the semiconductor devices 406, 408 within the cavity 402. Metal layers 504, 514 provides electrical connections to the semiconductor devices 406, 408. For example, a source contact 516 and a gate contact 518 of the semiconductor device 406 are provided through vias 502, while the metal layer 504 provides a drain connection to both semiconductor devices 406, 408 through vias 520. More specifically, as described and illustrated in the process flow of FIGS. 8-14, below, vias 502, 520 may be formed through the encapsulant 506, 508, 510, 512 to establish any needed electrical connections.

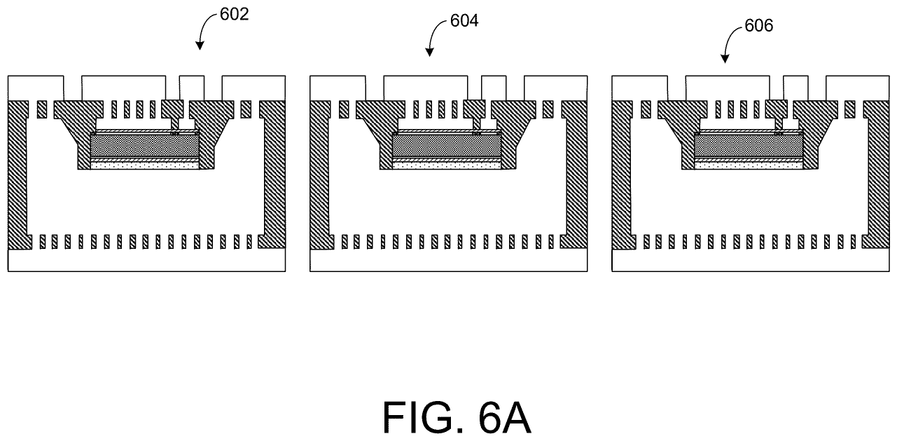

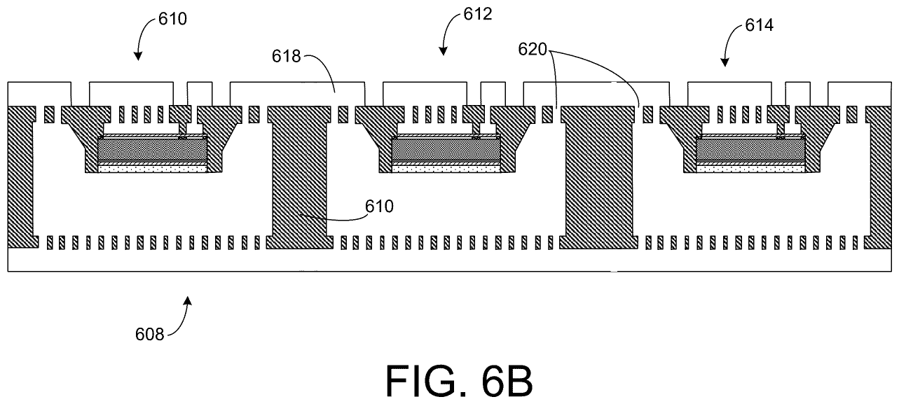

FIG. 6A illustrates a first example encapsulation of the embodiment of FIG. 2. In FIG. 6A, singulated embedded devices 602, 604, 606 are formed from the embodiment of FIG. 2, with encapsulations and electrical connections similar to those described and illustrated with respect to FIG. 5.

FIG. 6B illustrates a second example encapsulation of the embodiment of FIG. 2. In FIG. 6B, rather than being singulated, embedded devices 610, 612, 614 are included in a single joined panel 608. As shown, the drain potential of the different embedded devices 610, 612, 614 may be bridged by establishing additional copper plating 618 that extends through vias 620.

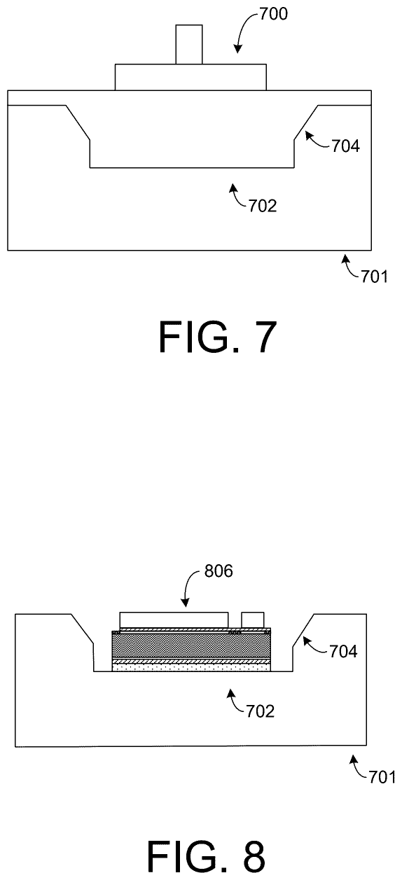

FIGS. 7-13 illustrate example operations for manufacturing embodiments of FIGS. 2-6B. FIG. 14 is a flowchart illustrating example operations for manufacturing the semiconductor device packages of FIGS. 1-6B, corresponding to the example operations of FIGS. 7-13.

In the example of FIG. 7, a cavity 702 with angled sidewalls 704 may be formed within a substrate 701 (1402 in FIG. 14), e.g., using a stamping tool 700. As shown, the stamping tool 700 may have a shape that, when stamped into the substrate 701, results in formation of the cavity 702 of a desired size, and having angled sidewalls 704 of a desired shape. Put another way, the stamping tool 700 may have a shape that is inverted with respect to a desired shape of the angled sidewalls 704 (e.g., is concave where the angled sidewalls are convex).

In this way, any desired shape or structure of the angled sidewalls 704 may be obtained, including formation of a chamfered edge as shown in FIG. 7 and illustrated and described above with respect to FIGS. 1 and 2A, or formation of a beveled edge as shown in FIG. 2B. More generally, any available or desired angle and/or length of each angled sidewall 704 may be obtained through selection of an appropriate, corresponding stamping tool 700.

Although FIG. 7 illustrates use of the stamping tool 700, other techniques may be used to provide the cavity 702 with angled sidewalls 704. For example, a chemical etching process may be used. Further, combinations of methods may be used. For example, as described with respect to FIG. 3, above, the cavity 702 may initially be formed with the angled sidewalls 704 having sharp edges/corners. Then, a chemical or mechanical process may be used to provide a reduction or elimination of the sharp edges/corners, e.g., to provide rounded-off corners. As a result, electric field densities may be reduced at the corners.

When a ceramic isolation layer is included, such as the isolation layer 219 of FIG. 2B, formation of the cavity 702 may occur in a manner(s) that takes into account a brittle nature of the isolation layer. For example, mechanical milling and/or chemical etching may be used.

FIG. 8 illustrates placement of a semiconductor device 806 within the cavity 702 (1404 in FIG. 14). As described above, the angled sidewalls 704 facilitate placement of the semiconductor device 806 within the cavity 702, e.g., by providing a relatively wide opening that enables centering of the semiconductor device 806 within the cavity 702. A bottom of the cavity 702 may be subjected to any suitable surface finish for die attach, and attachment may be executed using any suitable technique, such as sintering, soldering, or diffusion bonding.

Although FIGS. 7 and 8 illustrate examples with a single cavity 702 and semiconductor device 806, it will be appreciated that, as described above, the cavity 702 may be any suitable size, and two or more devices may be positioned within the cavity 702. Moreover, multiple instances of the examples of FIGS. 7 and 8 may be formed at once. That is, multiple cavities may be formed in a larger portion of substrate material (e.g., copper) using the techniques of FIGS. 7 (and 1402 in FIG. 14), and one or more semiconductor devices may be positioned within corresponding cavities using the techniques of FIGS. 8 (and 1404 in FIG. 14). Then, singulation may occur to obtain the result of FIG. 8.

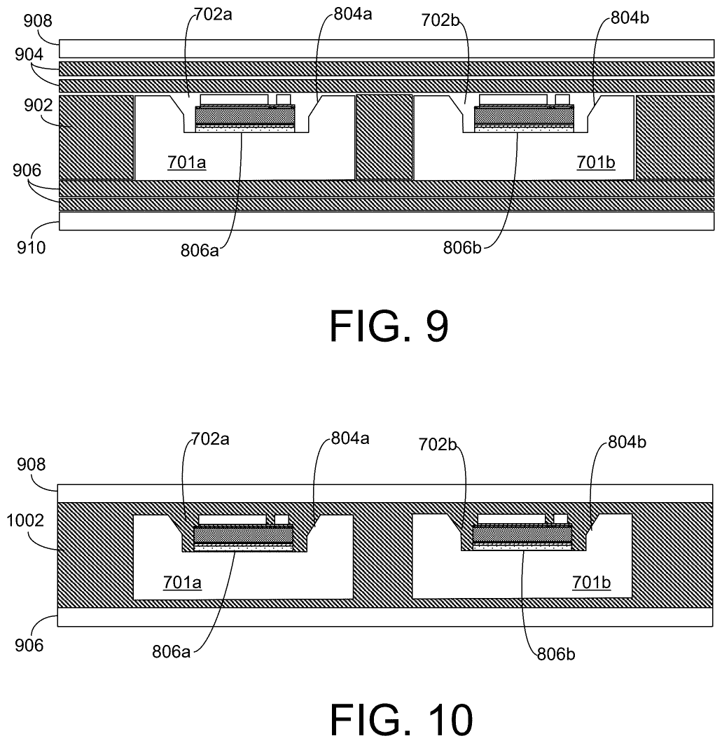

Examples of FIGS. 9-13 illustrate additional operations that may be performed prior to singulation, so that two substrates 701a/701b and two semiconductor devices 806a/806b are illustrated. That is, as shown, the substrate 701a includes a cavity 702a with angled sidewalls 704a, and the substrate 701b includes a cavity 702b with angled sidewalls 704b.

In FIG. 9, a lamination stack is prepared (1406 in FIG. 14). Specifically, the substrates 701a, 701b are encased in a core layer 902. The core layer 902 may include, e.g., any suitable material or composite material used for semiconductor packaging. For example, the core layer 902 may be formed from FR-4 (Flame Retardant 4), a composite material of woven fiberglass or other reinforcing material, impregnated with an epoxy resin. The core layer 902 may be prepared with cutouts in which the place the substrates 701a, 701b, as shown.

Further in FIG. 9, pre-preg layers 904 are positioned across a top of the core layer 902, the substrates 701a, 701b, and the semiconductor devices 806a, 806b. Similarly, pre-preg layers 906 are positioned across a bottom of the core layer 902, the substrates 701a, 701b, and the semiconductor devices 806a, 806b. Pre-preg layers 904, 906 generally refer to a reinforcing material, such as fiberglass or other fabrics, impregnated with a partially cured resin, such as epoxy. A copper layer 908 is positioned on the pre-preg layers 904, and a copper layer 910 is positioned on the pre-preg layers 906.

In FIG. 10, lamination and embedding are performed (1408 in FIG. 14). For example, vacuum embedding may be performed, in which heat and pressure are applied in a lamination process, causing the resin in the pre-preg layers 904, 906 to flow and cure, thereby forming a solid structure as encapsulant 1002. As referenced above, and as shown in FIGS. 9 and 10, the angled sidewalls 804a, 804b enable a full, complete, and reliable flow of the pre-preg layers 904 into the cavities 702a, 702b and around the semiconductor devices 806a, 806b.

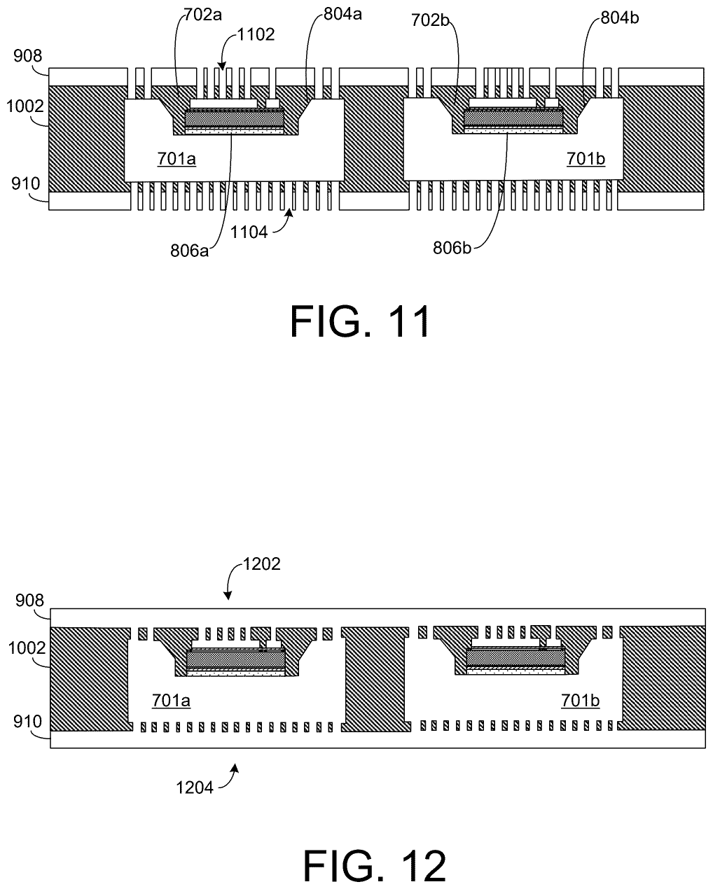

In FIG. 11, vias 1102, 1104 are formed for electrical interconnects (1410 in FIG. 14). For example, laser ablation processes or other techniques (e.g., drilling and/or etching) may be used.

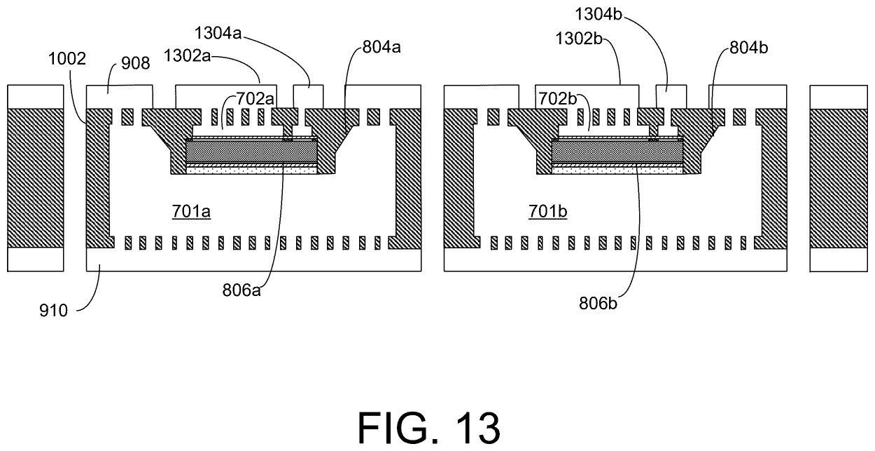

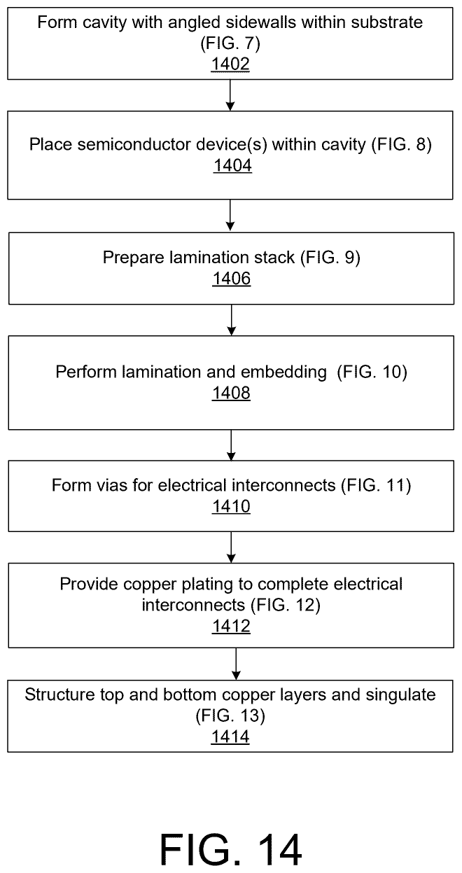

In FIG. 12, copper plating 1202, 1204 of the vias is provided to complete the electrical interconnects (1412 in FIG. 14). Then, in FIG. 13, the top and bottom copper layers 908, 910 may be structured to isolate the electrical interconnects formed previously. For example, as shown, a source connection 1302a and a gate connection 1304a may be established for the semiconductor device 806a, and a source connection 1302b and a gate connection 1304b may be established for the semiconductor device 806b.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

In some implementations, a DBM substrate can be formed by bonding one or more metal layers (e.g., a first metal layer, second metal layer) to an insulating layer. In some implementations, one or more of the metal layers can be bonded to the insulating layer using, for example, a high-temperature process.

In some implementations, a DBM substrate can include an insulating layer disposed between the first metal layer and the second metal layer. The insulating layer can be, for example, a ceramic layer. In some implementations, the insulating layer can be or can include, for example, a ceramic material such as alumina (Al₂O₃) or aluminum nitride (AlN)).

In some implementations, the first metal layer and/or the second metal layer can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate. In some implementations, such as in DBC substrate implementations, the first metal layer and/or the second metal layer is a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor dies may be also connected to lead frame posts by electrical connections such as wirebonds or clips.

In example implementations, a package (e.g., a power module) can be a hybrid device package that includes a semiconductor die or a plurality of semiconductor dies that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate.

In some implementations, a mold material (e.g., molding material or compound, an encapsulation material) can be or can include a non-conducting layer/material.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer)

In some implementations, a module (e.g., a package including a semiconductor device) can be included in another module. The module can be referred to as a package. For example, one or more modules can be one or more sub modules included within another module. In other words, a first module can be included as a sub module within a second module.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A semiconductor device package, comprising:
a conductive member having a cavity formed therein, the cavity having at least one sidewall with an angled portion that is angled away from a middle portion of the cavity; and
a semiconductor device positioned within the cavity.

2. The semiconductor device package of claim 1, further comprising:
mold material formed around the semiconductor device and within the cavity.

3. The semiconductor device package of claim 1, wherein the at least one sidewall has a chamfered edge, wherein the chamfered edge includes a perpendicular portion that is perpendicular to a floor of the cavity and the angled portion is joined to the perpendicular portion.

4. The semiconductor device package of claim 3, wherein a corner formed between the perpendicular portion and the angled portion is rounded.

5. The semiconductor device package of claim 1, wherein the at least one sidewall has a beveled edge.

6. The semiconductor device package of claim 1, wherein the conductive member is a metal leadframe.

7. The semiconductor device package of claim 1, wherein the cavity is rectangular.

8. The semiconductor device package of claim 7, wherein at least one corner of the cavity is rounded.

9. The semiconductor device package of claim 1, further comprising:
an isolation layer disposed on a side of the conductive member opposite the cavity; and
a second conductive member disposed on the isolation layer.

10. A package for an embedded semiconductor device, the package comprising:
a substrate having a cavity formed therein, the cavity having at least one angled sidewall;
at least one semiconductor device disposed within the cavity; and
an encapsulant surrounding the at least one semiconductor device within the cavity.

11. The package of claim 10, wherein the angled sidewalls each have a chamfered edge, wherein the chamfered edge includes a perpendicular portion that is perpendicular to a floor of the cavity and an angled portion is joined to the perpendicular portion.

12. The package of claim 11, wherein a corner formed between the perpendicular portion and the angled portion is rounded.

13. The package of claim 10, wherein the angled sidewalls are angled away from a center of the cavity.

14. The package of claim 10, wherein the angled sidewalls each have a beveled edge.

15. The package of claim 10, wherein the substrate includes a metal leadframe.

16. A method of forming a semiconductor device package, comprising:
forming a cavity within a substrate, the cavity having at least one angled sidewall;
disposing at least one semiconductor device within the cavity; and
encapsulating the at least one semiconductor device within the cavity with an encapsulant.

17. The method of claim 16, wherein forming the cavity comprises forming the cavity using a mechanical stamp.

18. The method of claim 16, wherein forming the cavity includes forming the at least one angled sidewall with chamfered edge.

19. The method of claim 16, wherein forming the cavity includes forming the at least one angled sidewall angled away from a center of the cavity.

20. The method of claim 16, wherein encapsulating the at least one semiconductor device comprises:
providing at least one layer of pre-preg material across a top of the substrate, the cavity, and the at least one semiconductor device; and
performing a lamination process to cause the at least one layer of pre-preg material to flow into the cavity and cure, to thereby provide the encapsulant.
